(19) United States
(12) Patent Application Publication
(10) Pub. No.: US 2008/0128762 A1
(43) Pub. Date: Jun. 5, 2008

(54) Junction isolated poly-silicon gate JFET

(76) Inventor: Madhukar B. Vora, Los Gatos, CA (US)

Correspondence Address: BAKER BOTTS L.L.P., 2001 ROSS AVENUE, SUITE 600, DALLAS, TX, 75201-2980, US

(21) Appl. No.: 11/590,376

(22) Filed: Oct. 31, 2006

(51) Int. Cl. H01L 29/76; H01L 21/337

(52) U.S. Cl. 257/288; 257/504; 438/186

(57) ABSTRACT

An integrated Junction Field Effect Transistor is disclosed which is much smaller and much less expensive to fabricate because it does not use Shallow Trench Isolation or field oxide in the semiconductor substrate to isolate separate transistors. Instead, a layer of insulating material is formed on the top surface of said substrate, and interconnect trenches are etched in said insulating layer which do not go all the way down to the semiconductor substrate. Contact openings are etched in the insulating layer all the way down to the semiconductor layer. Doped poly-silicon is formed in the contact openings and interconnect trenches and silicide is formed on tops of the poly-silicon. This contact and interconnect structure applies to any integrated transistor. The integrated JFET disclosed herein does not use STI or field oxide and uses junction isolation. A conventional JFET is built in a P-well. The P-well is encapsulated in an N-well which is implanted into the substrate. Separate contacts to the P-well, N-well and substrate are formed as well as to the source, drain and gate so that the device can be isolated by reverse-biasing a PN junction. Operating voltage is restricted to less than 0.7 volts to prevent latching.

### BACKGROUND OF THE INVENTION

In the early day of bipolar transistor integration, aluminum contact wires were used. They ran across fields of silicon dioxide which were deposited on the surface of the substrate and then dipped down into contact holes for emitter, base and collector. Since the silicon dioxide layer was about 5000 angstroms thick, step coverage was a problem because the aluminum often would break down at the step and cause an open circuit. Isolation between active areas was accomplished using diffused PN junctions. Basically, P-type isolation diffusions were made into N-epitaxial layers to create PN junctions at the walls of the active areas between the P-type diffusion and the N-type epitaxial silicon. This created N-type islands of N-epitaxial silicon which were isolated from the substrate and each other by reverse-biased diodes. Hamilton and Howard, Basic Integrated Circuit Engineering, FIG. 1-6, p. 13 (McGraw Hill 1975), the entirety of which is hereby incorporated by reference (hereafter, just Hamilton).

That reverse-biased PN-junction isolation method had several problems. Specifically: 1) the time required for the isolation diffusion was considerably longer than any other diffusions; 2) because lateral diffusion was great during the long isolation diffusions, considerable clearance had to be used for the isolation regions, and because those isolation diffusions occurred at the perimeter of the device, considerable chip area was wasted, which cut down on device density; 3) the relatively deep sidewalls and large area of isolation regions contributed significant parasitic capacitance which degraded circuit performance.

In response to those problems, several isolation methods were developed in the prior art which avoided the use of isolation diffusion. One of these was the Fairchild Isoplanar II process which is described at Hamilton, pp. 83-84 and FIG. 3-1. This process grew an N-epitaxial layer (hereafter just epi) on a P-substrate and etched isolation trenches in the epi. Silicon dioxide was then thermally grown in the isolation trenches to isolate the active areas. A layer of insulating material with a contact hole in it over the active area was used to allow an emitter contact to be made and a base contact was made at the edge of this layer of insulating material. This process still had step coverage issues for the emitter and base contact “wires”. This led to the Shallow Trench Isolation method of isolating active areas, because, as device geometry continued to shrink, the step coverage issue became more of a problem at the smaller geometry. Shallow Trench Isolation was more planar and eliminated step coverage issues.

Forming Shallow Trench Isolation (STI) areas around each device on an integrated circuit typically costs about one-third of the total fabrication cost of the chip. Elimination of the STI steps would simplify the chip fabrication process and render it less expensive. Elimination of the STI area would also make the total chip area consumed by each device less, so more complicated circuits with more transistors could be put on the same size die. Yield is generally proportional to die size. The bigger the die, the lower the yield. Being able to put a circuit on a smaller die by virtue of elimination of the STI isolation means the yield will go up and the cost per chip will go down. Likewise, elimination of STI would make it possible to put more complicated circuits with more transistors on smaller dies than previously was possible, so the cost per circuit goes down with the increasing yields.

The presence of STI isolation eliminates a small amount of junction capacitance which would otherwise exist. The structures which cause this junction capacitance in a JFET are shown in FIG. 1, which is a cross-section through a prior art JFET. With STI areas 5, 6 and 7 present, the junction capacitance of ohmic contact junctions 2 and 4 for the source and drain regions and the junction capacitance of the junction 3 of the P-well ohmic contact are limited by the actual area of the junction with the P-well. The presence of the STI cuts off some of the junction area (the cut off junction area is represented by the dashed lines) because if the STI were not present, these junctions 2, 3 and 4 would continue to the surface of the substrate as shown by the dashed lines. The junction areas represented by these dashed lines would contribute parasitic junction capacitance to the device, but not very much. The addition of STI prevents this parasitic capacitance from being present, but when STI is eliminated, the small amount of parasitic capacitance represented by the dashed line continuations of the junctions 2, 3 and 4 would exist.

Another reason why STI was added to integrated circuit structures in general was to prevent SCR-like latching. A typical integrated circuit structure without STI isolation layers present is shown in FIG. 2. Many different semiconductor structures in the MOS, CMOS, JFET and other semiconductor technologies can exist. FIG. 2 is just one typical example in the JFET realm. However, in any integrated circuit transistor structure, if four different semiconductor layers are joined together without interruption so as to form a P N P N structure like that shown in FIG. 3 (or an NPNP structure), SCR-like latching can occur if the bias across the PNPN structure between points A and B exceeds 0.7 volts. Any CMOS, MOS or JFET structure without STI isolation will have a four-layer PNPN structure in it somewhere, so SCR-like latch-up can occur and destroy the utility of the circuit.

If one were to plot the current from A to B as a function of voltage for the structure of FIG. 3, a characteristic curve like that shown in FIG. 4 would be found to exist. The voltage at the breakpoint C in the curve where latch-up occurs is always 0.7 volts. This latching destroys the operability of the device for its intended function. The PNPN or NPNP structure is a very common structure that will be found in any triple-well process.

The presence of STI prevents any such PNPN (or NPNP) structure from existing by isolating transistors from their neighbors so that a PNPN structure between neighboring transistors cannot exist.

The elimination of STI and field oxide however brings a new set of problems with regard to interconnection of devices. In JFET and MOS and CMOS circuits, it is frequently necessary to connect one or more terminals of a first transistor to one or more terminals of a second transistor elsewhere on the die. A simple example of this is shown in FIG. 5. FIG. 5 is a partial schematic diagram of a prior art JFET inverter showing how the drain of the P-channel JFET is connected to the drain of the N-channel JFET and showing how the gate of the P-channel JFET is connected to the gate of the N-channel JFET. Since these devices are typically located adjacent to each other on the die, and since the source, drain and gate contacts are made of conductive material, it is convenient to extend the conductive material that fills the gate contact opening outside the active area of one transistor, across the field of substrate between the two active areas of the two transistors to join with the conductive material of the other transistor thereby eliminating the need to make this connection on upper metal conductive layers to be formed later.

FIG. 6 is a illustration of how the doped poly-silicon structures that make contact to source, gate or drain regions of prior art JFET or MOS or CMOS transistors can be extended from one active area 13 to the next active area 15 across an area 17 of the substrate at which field oxide or STI formed an insulating surface in the prior art. FIG. 7 is a cross-sectional view of the prior art poly-silicon interconnect 9 of FIG. 6. This figure shows three things: first, it shows how if doped poly-silicon is used to make the interconnect 9, unintended PN junctions such as PN junction 13 can be formed; second, it shows how a layer of silicide 11 was formed in the prior art on top of the doped poly-silicon to short out any unintended PN junctions 7 in the poly-silicon; and, third, it shows how the STI or field oxide 17 insulates the interconnect from making electrical contact with anything in the substrate it is not intended to make contact with and prevents the interconnect 9 from being shorted to whatever voltage source is connected to the conductive substrate. If the interconnect 9 were to be in electrical contact with the conductive substrate, this would alter the voltage applied to the terminals of both transistors to which interconnect 9 is connected and prevent them from operating properly.

Elimination of the STI or field oxide creates the new problem of how to use the conductive materials used to make contact with the source, drain and/or gate terminals to double as an interconnect to terminals of other transistors on the die. A subsidiary problem is how to make such an interconnect structure planar so as to eliminate step coverage problems and photolithographic problems at very small linewidths.

Therefore, a need has arisen for a junction-isolated JFET, MOS or CMOS device with no STI and a new interconnect structure which can be used to permit the conductive materials used to make contact to the source, drain and gate terminals (or other terminals) to double as interconnects to other transistors, and how to make that interconnect structure planar on top.

### BRIEF DESCRIPTION OF THE DRAWINGS

FIG. 1 is a prior art JFET structure used to illustrate the parasitic junction capacitance which the presence of STI cuts off.

FIG. 2 is a cross-section of a typical integrated semiconductor structure without STI to illustrate the latching problem which the presence of STI solves.

FIG. 3 is a diagram of a four-layer semiconductor structure which will latch if the bias across the four layers exceeds 0.7 volts.

FIG. 4 is a characteristic curve of current versus voltage which is typical of the latching phenomenon in any PNPN structure of an integrated circuit.

FIG. 5 is a partial schematic diagram of a prior art inverter showing how the source of the P-channel JFET is connected to the drain of the N-channel JFET.

FIG. 6 is a illustration of how the doped poly-silicon interconnects that make contact to source, gate or drain regions of JFET or MOS devices typically extend from one active area to the next across areas of the substrate at which field oxide or STI forms an insulating surface.

FIG. 7 is a cross-sectional view of the poly-silicon interconnect of FIG. 6 showing how silicide is formed on top thereof to short out any unintended PN junctions in the poly-silicon, and showing how the STI insulates the interconnect from making unintended electrical contact with anything in the substrate.

FIG. 8 is comprised of: FIG. 8A which is a cross-section through the finished device active area (less contact holes and metalization); FIG. 8B, which is a cross-section through the finished device at the gate; FIG. 8C which is a cross-section through the finished device at the source; and FIG. 8D which is a top view of the finished device looking down on the active area (silicide on top of the poly-silicon contacts is not shown).

FIGS. 9A through 9D are views through the JFET structure of the invention at an intermediate stage of construction including a cross-section through the active area (FIG. 9A) and cross sections through the gate (FIG. 9B) and source (FIG. 9C) of a JFET device without STI isolation after the first few steps in the process of construction to form the N-well implant. FIG. 9D is a plan view of the structure.

FIGS. 10A through 10D are views through the JFET structure of the invention at an intermediate stage of construction including a cross-section through the active area (FIG. 10A) and cross sections through the gate (FIG. 10B) and source (FIG. 10C) of JFET device without STI isolation after the first few steps to form the N-well implant and the P-well implant. FIG. 10D is a plan view of the structure.

FIGS. 11A through 11D are views through the JFET structure of the invention at an intermediate stage of construction including a cross-section through the active area (FIG. 11A) and cross sections through the gate (FIG. 11B) and source (FIG. 11C) of JFET device without STI isolation after the first few steps to form the N-well implant and the P-well implant. FIG. 11D is a plan view of the structure.

FIGS. 12A through 12D are views through the JFET structure of the invention at an intermediate stage of construction including a cross-section through the active area (FIG. 12A) and cross sections through the gate (FIG. 12B) and source (FIG. 12C) of JFET device without STI isolation after the first few steps to form the N-well implant and the P-well implant and the N-type channel implant. FIG. 12D is a plan view of the structure.

FIGS. 13A through 13D show the structure at a stage of construction after the N-well, P-well, N-type channel have been formed and the active area has been defined and thick layer of silicon dioxide 78 has been deposited.

FIGS. 14A through 14D show the structure at a stage of construction after the N-well, P-well, N-type channel have been formed and the active area has been defined and thick layer of silicon dioxide has been deposited and polished back to a planar state.

FIGS. 15A through 15D show the structure at a stage of construction after the N-well, P-well, N-type channel have been formed and the active area has been defined and thick layer of silicon dioxide has been deposited and polished back and a plurality of contact holes have been masked and etched.

FIGS. 16A through 16D show the structure at a stage of construction after the N-well, P-well, N-type channel have been formed and the active area has been defined and a thick layer of silicon dioxide has been deposited and polished back and a plurality of contact holes have been masked and etched, and the contact holes have been filled with poly-silicon and the poly-silicon has been polished back.

FIGS. 17A through 17D show the structure at a stage of construction after the N-well, P-well, and N-type channel have been formed and the active area has been defined and a thick layer of silicon dioxide has been deposited and polished back and a plurality of contact holes have been masked and etched, and the contact holes have been filled with poly-silicon and polished back, and a P+ impurity implant mask has been formed and a P+ implant has been completed.

FIGS. 18A through 18D show the structure at a stage of construction after the N-well, P-well, and N-type channel have been formed and the active area has been defined and a thick layer of silicon dioxide has been deposited and polished back and a plurality of contact holes have been masked and etched, and the contact holes have been filled with poly-silicon and polished back, and an implant mask has been formed and an N+ impurity implant has been completed.

### SUMMARY OF THE INVENTION

The teachings of the invention contemplate a method and device structure to build a Junction Field Effect Transistor using junction isolation only, with no Shallow Trench Isolation (STI), and a novel method of forming the active area and a novel way of forming the source, drain and gate regions and interconnects between active areas. A restriction exists that the device operating voltage must not exceed 0.7 volts; this is to prevent the latching problem known in the prior art when no STI is used. In the preferred embodiment, operating voltage is restricted to 0.5 volts to ensure no latching in any PNPN structure which may be formed.

The omission of STI can be applied to any integrated semiconductor structure in the MOS, bipolar, CMOS or JFET families so long as the operating voltages can be restricted to 0.5 volts and the devices will work at that voltage.

A new method of fabrication of poly-silicon interconnect “wires” and a new resulting device structure is also disclosed. This new method of fabrication and resulting device structure is made necessary by the elimination of the STI insulation between active areas thereby requiring the addition of the insulating layer (a sandwich of insulating materials in the preferred embodiment) on top of the substrate outside the active area and covering the active area except in the location of contact openings down to the surface of the active area. In the prior art devices, STI insulation material was formed in the substrate and came up to the surface of the substrate between active areas of devices that needed to be interconnected. For example, in a JFET inverter, the drain of the P-channel JFET needs to be interconnected to the drain of an N-channel JFET. In the prior art, this could be done by extending the drain contact poly-silicon of the N-channel JFET outside the N-channel active area and across the STI field to join with an extension of the drain contact poly-silicon of the P-channel JFET. In cross-section, this prior art poly-silicon “wire” has a uniform thickness all the way from the P-channel device to the N-channel device.

When the STI is eliminated, this structure cannot be used because the conductive poly-silicon interconnect wire will be in electrical contact with the top of the conductive substrate and would be shorted to whatever voltage source the substrate is connected to. Further, the interconnect wire could short junctions that come to the surface of the substrate under it. Since the source- and drain- and gate-contact poly-silicon or metal interconnect “wires” all run across what used to be the STI insulation field, the electrical contact between these “wires” through the conductive substrate shorts them out and eliminates the ability to apply different bias voltages to the source, drain and gate of the JFET, thereby rendering it inoperative.

To prevent this undesirable result, a layer of insulation is deposited on top of the substrate between devices that need to be interconnected by conductive extensions of the source, drain or gate lines contact structures. This insulating material deposited on top of the substrate performs the insulating function of the STI in the prior art. Poly-silicon is then deposited in the contact holes and over the top of the insulating layer on top of the substrate and etched to form the desired interconnect “wire”, and then is polished back so as to have a flat top surface. The idea is to eliminate step coverage issues for structures such as metal interconnects that need to pass over the poly-silicon interconnects. The poly-silicon itself of the gate contact and its extension as an interconnect “wire” is deposited into the gate contact hole and makes contact with the active area. A layer of silicon dioxide, silicon nitride and more silicon dioxide is used to insulate the source-, gate- and drain-interconnect wires from making electrical contact with the conductive substrate outside the active area or the active areas of neighboring devices. The poly-silicon interconnect “wires” have greater thickness in the contact holes than outside them. This would normally lead to a top surface of the poly-silicon interconnect wire having an uneven quality because it would dip down in the area where the contact hole was located. This dip would be mirrored in the top surface of any insulating layer deposited over the poly-silicon interconnect “wire”. This would normally create a step coverage issue for structures such metal interconnect lines that are deposited on top of the insulating layer over the poly-silicon interconnect. However, in the structures according to the teachings of the invention, a chemical-mechanical-polish step is used to polish the tops of the poly-silicon interconnect wires back to flush with the top surface of the insulating layer (typically a sandwich of silicon dioxide, silicon nitride, and more silicon dioxide). This sandwich insulating structure defines the active areas and covers the fields of substrate between devices. Because the top surfaces of these poly-silicon interconnect “wires” is flat after the polishing step, there is no step coverage issue—even though STI has been eliminated.

### DETAILED DESCRIPTION OF THE VARIOUS EMBODIMENTS

### Preferred Embodiment

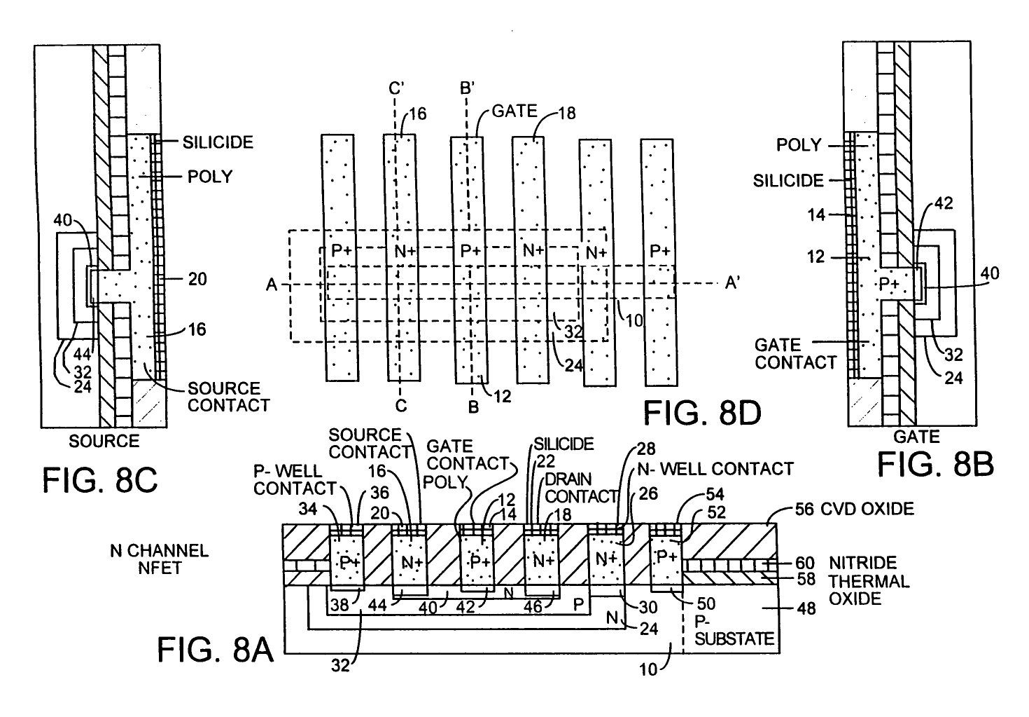

FIG. 8 is comprised of FIGS. 8A through 8D, and shows the details of the finished device. FIG. 8A is a cross-section through the finished device active area, less contact holes and metallization, and is section AA′ in FIG. 8D. FIG. 8B is a cross-section through the finished device at the gate (section BB′ in FIG. 8D). FIG. 8C is a cross-section through the finished device at the source (Section CC′ in FIG. 8D). FIG. 8D is a top view of the finished device looking down on the active area (silicide on top of the poly-silicon contacts is not shown). The finished device structure will be discussed with reference to all of FIGS. 8A through 8D. Dashed line 10 in FIG. 8D is the outline of the active area. A region of P+ doped poly-silicon 12 is the gate contact. The gate contact poly-silicon has silicide 14 formed on top thereof to reduce its resistance and to short out any PN junctions which are inadvertently formed if the gate poly-silicon 12 is extended to make contact with an N+ doped poly-silicon contact of another device elsewhere on the circuit. N+ doped poly-silicon area 16 is the source contact. N+ doped poly-silicon area 18 is the drain contact. Each of the source and drain contacts has a silicide layer, 20 and 22, respectively, formed on top thereof which serves the same purpose as the silicide layer on top of the gate contact.

A triple-well and junction isolation structure is used instead of using field oxide or Shallow Trench Isolation (STI) for device isolation. An N-doped well 24 is formed in the P-substrate 48. N+ impurities diffused out the N+ poly-silicon 26 form an N+ diffusion region 30. N+ poly-silicon forms an ohmic contact to N-doped well 24 through N+ diffusion region 30 which is formed in the active area 10. A P-doped well 32 formed inside the N-well 24 is in electrical contact with an ohmic contact 38 which is in electrical contact with a P+ doped poly-silicon contact 34 with a layer of silicide 36 on top thereof.

An N-type channel region 40 is formed in the P-well 32. In that channel region a gate region 42, a source region 44 and a drain region 46 are formed. Gate region 42, source region 44 and drain region 46 are each formed by driving impurities from the overlying doped poly-silicon contact into the substrate in a diffusion step to form self-aligned gate, source and drain regions.

A P− doped substrate 48 is in electrical contact with an ohmic contact 50 which is in electrical contact with a P+ doped poly-silicon contact 52 which has a layer of silicide 54 formed on the surface thereof. Ohmic contact 50 is formed by diffusing impurities out of the P+ doped poly-silicon contact 52 into the underlying substrate. The same is true for ohmic contact 38.

The areas which have the cross-hatching to the left like area 56 are silicon dioxide deposited by Chemical Vapor Deposition (CVD). The areas which have the cross-hatching to the right like area 58 are thermally grown silicon dioxide. Typical thickness for layer 58 is about 1000 angstroms (A). The areas which have the vertical cross-hatching like area 60 are an etch stop material such as silicon nitride (hereafter just nitride) or aluminum oxide or intrinsic undoped polysilicon or any other insulator which will stop a plasma etch. Typical thickness for the etch stop layer 60 is about 200 A. Typical thickness for the insulating layer 56 is about 3000 A.

### Alternative Embodiments

The substrate 48 can be any semiconductor substrate selected from a group comprising silicon, germanium, silicon-carbide and silicon-germanium-carbon alloy. The term “substrate” should be interpreted to mean any of these semiconductors.

In alternative embodiments, the channel region 40 and gate region 42, the source and drain regions and the N-well 24 and the P-well 32 can be formed in epitaxially deposited silicon or silicon-germanium-carbon alloy material deposited on the substrate or on an insulating material.

In alternative embodiment, the gate region 42 comprises silicon-germanium-carbon alloy or a plurality of silicon-germanium-carbon alloy layers.

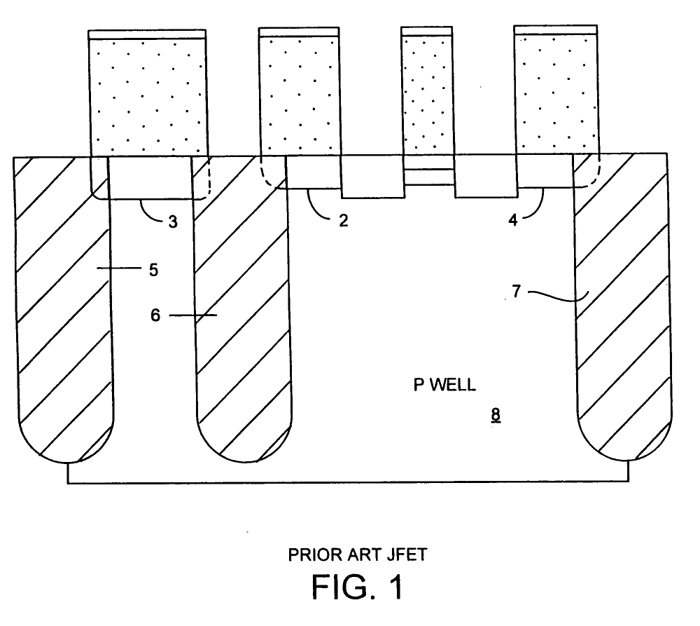

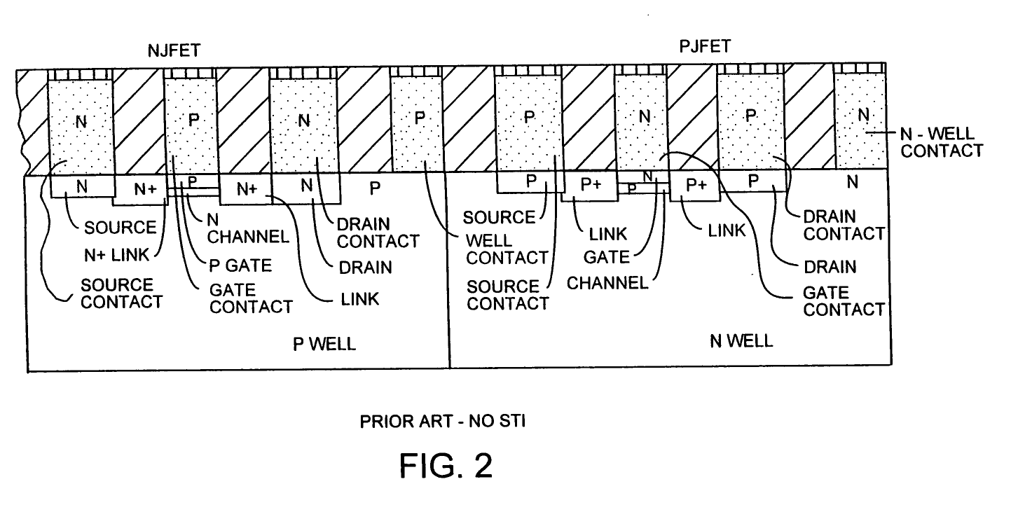

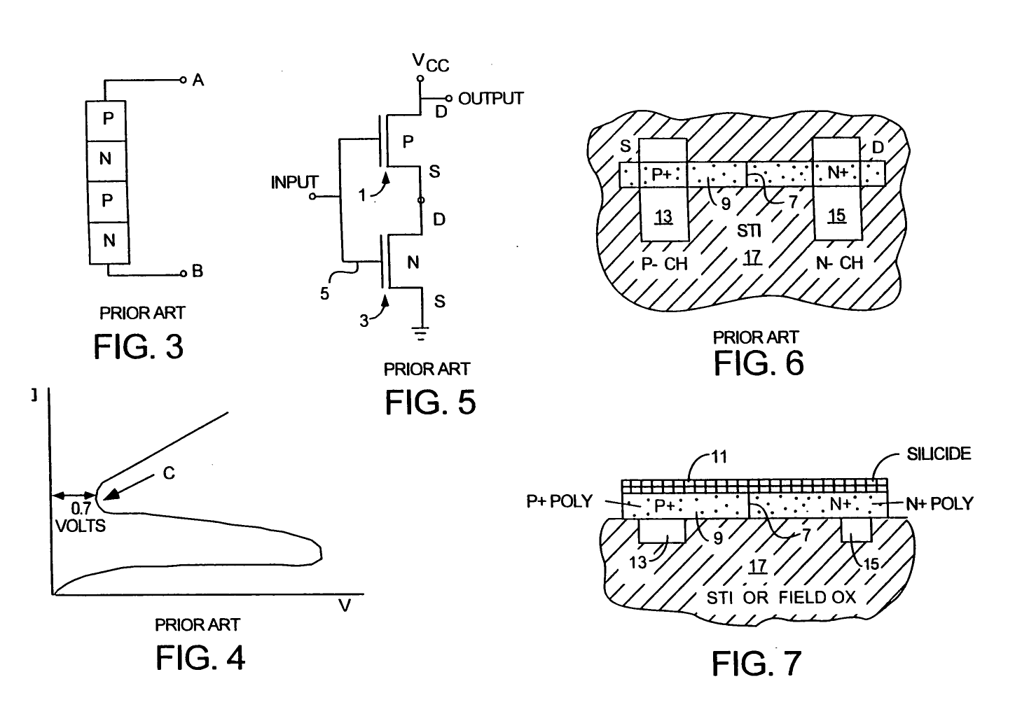

The junction field effect transistor having the structure shown in FIG. 1A is sometimes included in a circuit including at least one MOS transistor and/or at least one bipolar transistor.

### The Process of Manufacture of The Preferred Embodiment

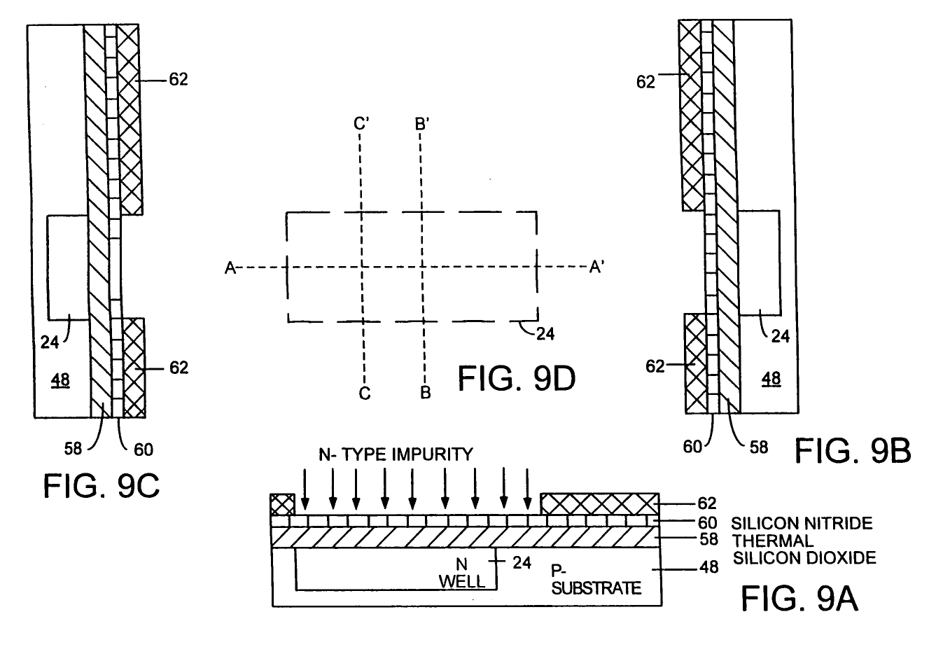

The process of manufacture is summarized in table 1 below. The process will be described starting with FIGS. 9A through 9D which show the device at an early stage of construction. FIG. 9(A) is a cross-section along section line A-A′ in FIG. 9(D), which is a top view of the device after the first few steps to form the N-well implant and deposit an insulating layer sandwich over the entire substrate. Starting with P− doped semiconductor substrate 48 such as silicon, a layer of silicon dioxide 58 (hereafter oxide) is thermally grown to a thickness of about 100 angstroms (A). A layer of silicon nitride 60 (hereafter nitride) is then deposited on the thermal oxide to a thickness of about 200 A. A photoresist mask 62 is then formed to mask off the area where an N-type well 24 is to be implanted. An N-type impurity implant is then performed to form N-well 24. The N-well isolates the JFET constructed therein from surrounding structures. Typical implant energy is 200 KEV with a dose of 1E13. An N-well drive-in at 950 degrees C. is then performed to anneal the implant and activate the implanted impurities such that they insert themselves into the crystal lattice.

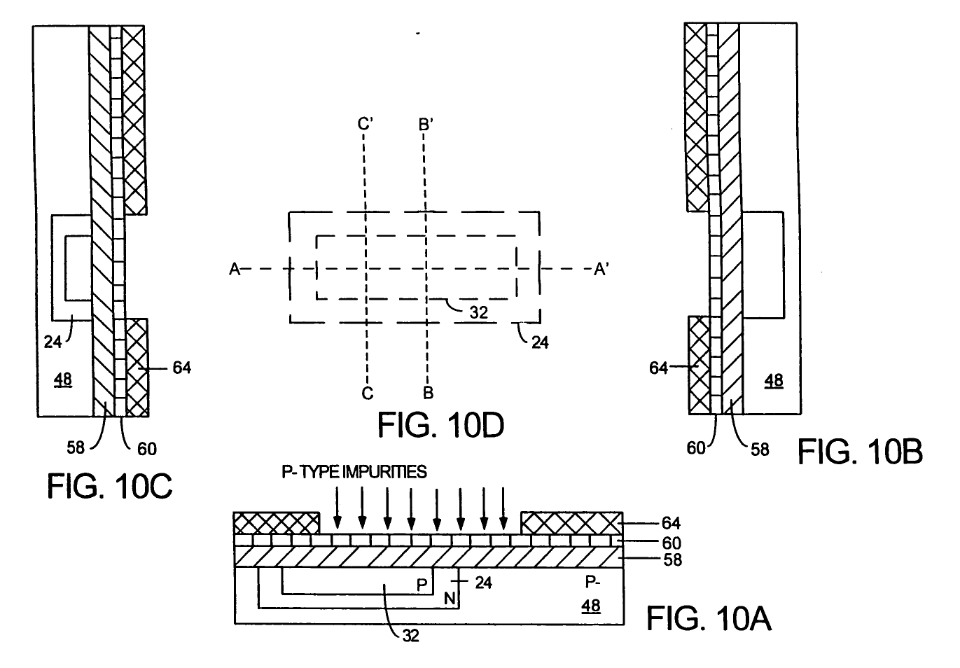

FIGS. 10A through 10D are views including a cross-sections of FIGS. 10A,10B and 10C along section lines A-A′, B-B′ and C-C′ in the plan view of FIG. 10D. FIG. 10 describes the formation of the P-well. To reach this stage, the mask 62 of FIG. 9 is removed and a new mask 64 in FIG. 10 is formed to expose the area where the P-well 32 is to be formed. A P-type impurity implant is then performed to form P-well 32 inside N-well 24. Typical implant energy is 50 KEV with a dose of 3E13. A P-well drive-in at 950 degrees C. is then performed.

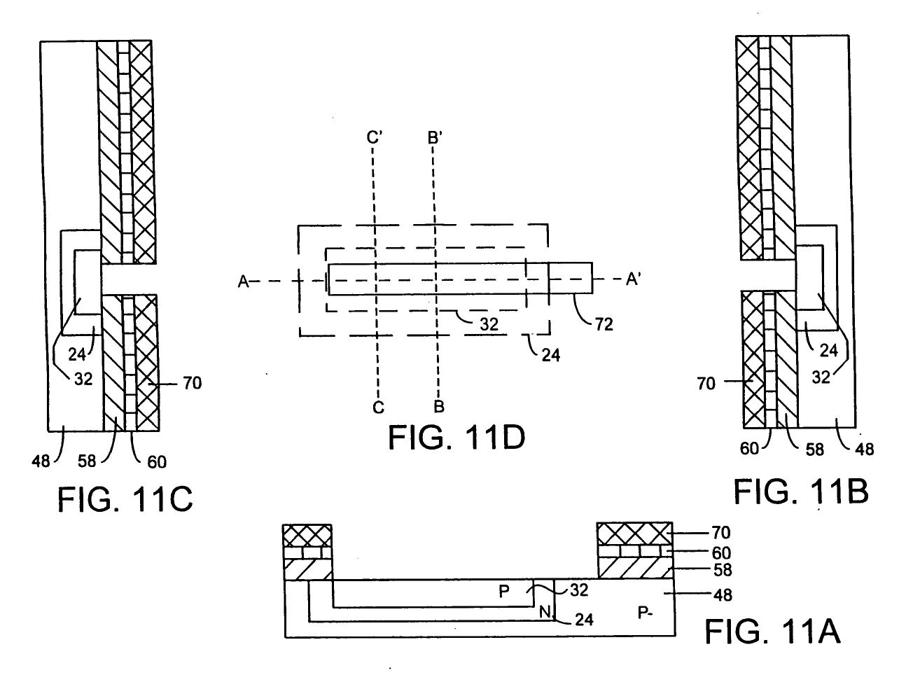

FIGS. 11A through 11D describe formation of the Active area. FIG. 1D is a plan view of the structure. FIG. 11A, 11B and 11C are section views of the device structure along section lines A-A′ B-B′ and C-C′ in FIG. 11D, respectively. To reach the point illustrated in FIG. 10, a photo-resist layer 70 is formed so as to expose the nitride layer 60 and the oxide layer 58 to define the desired area for the active area 72. The nitride layer 60 and oxide layer 58 is then etched to expose the top of the substrate at the location of the active area 72. Preferably a plasma etch is used which is set up to detect the presence of silicon atoms in the gases formed during the etching process so that the etching stops as soon as the surface of the substrate 48 is reached. This etching process to etch nitride over oxide and stop at the substrate is well known in the art. Any way of etching through the nitride and oxide layers and stopping at the surface of the substrate will suffice to practice the invention.

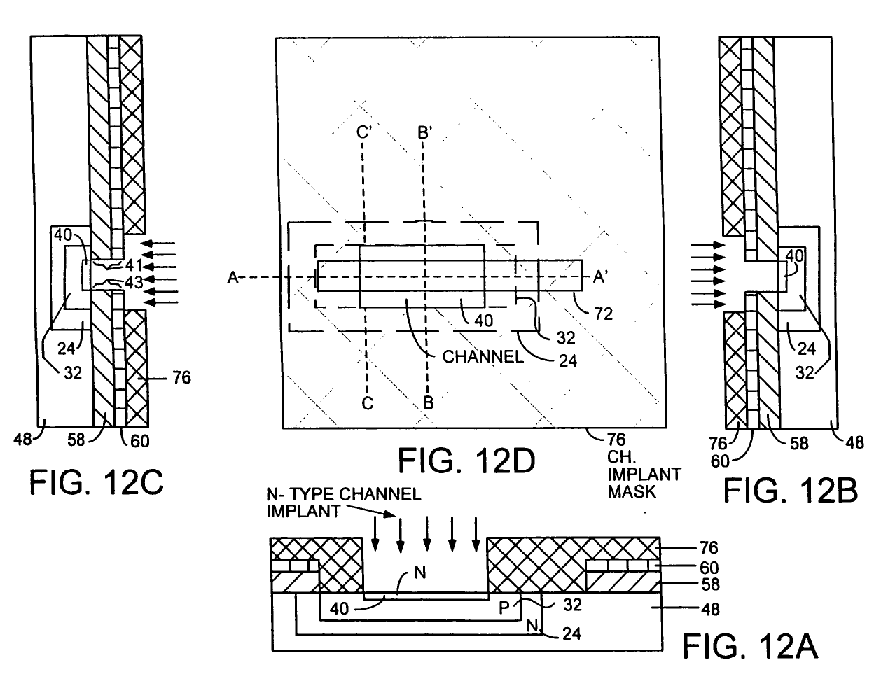

FIGS. 12A through 12D are views including a cross-section through the active area (FIG. 12A) of and cross sections through the gate (FIG. 12B) and source (FIG. 12C) of JFET device without STI isolation after the first few steps to form the N-well implant and the P-well implant and showing the channel implant mask 76 and the channel implant. FIG. 12D is a plan view of the structure. To reach the stage illustrated in FIG. 12, the previous mask 70 is removed, and a new channel implant mask 76 is formed to expose only the area where the N-type, conductivity-enhancing impurities are to be implanted to form an N-type—channel 40. Multiple implants with energies at 15 KEV, dose 1E13 followed by 37 KEV, dose 4E11 are preferred so as to form a channel-well junction depth of approximately 40-50 nanometers. The implant energies are kept low enough such that the nitride layer 60 and the underlying thermal silicon dioxide layer 58 are thick enough to prevent impurity ions from passing through them into the underlying substrate. This forms a self-aligned channel 40 which aligned with the edges 41 and 43 of the nitride layer 60 and the silicon dioxide layer 58.

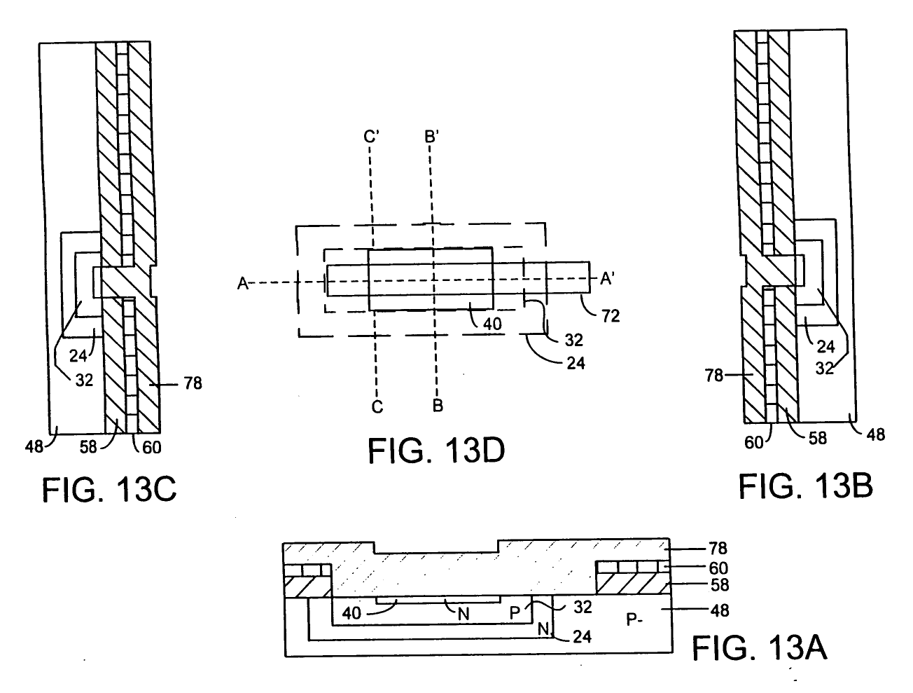

FIGS. 13A through 13D show the structure at a stage of construction after the N-well, P-well and N-type channel have been formed and the active area has been defined and a thick layer of silicon dioxide has been deposited. To reach this stage, mask 76 is removed, and a layer of silicon dioxide about 7000 A thick is deposited by CVD.

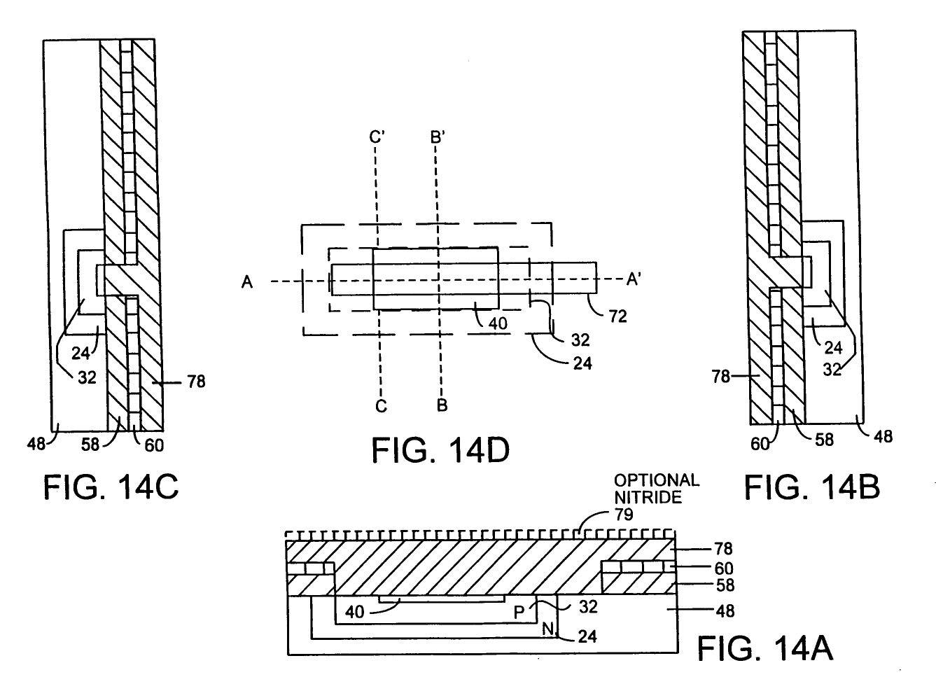

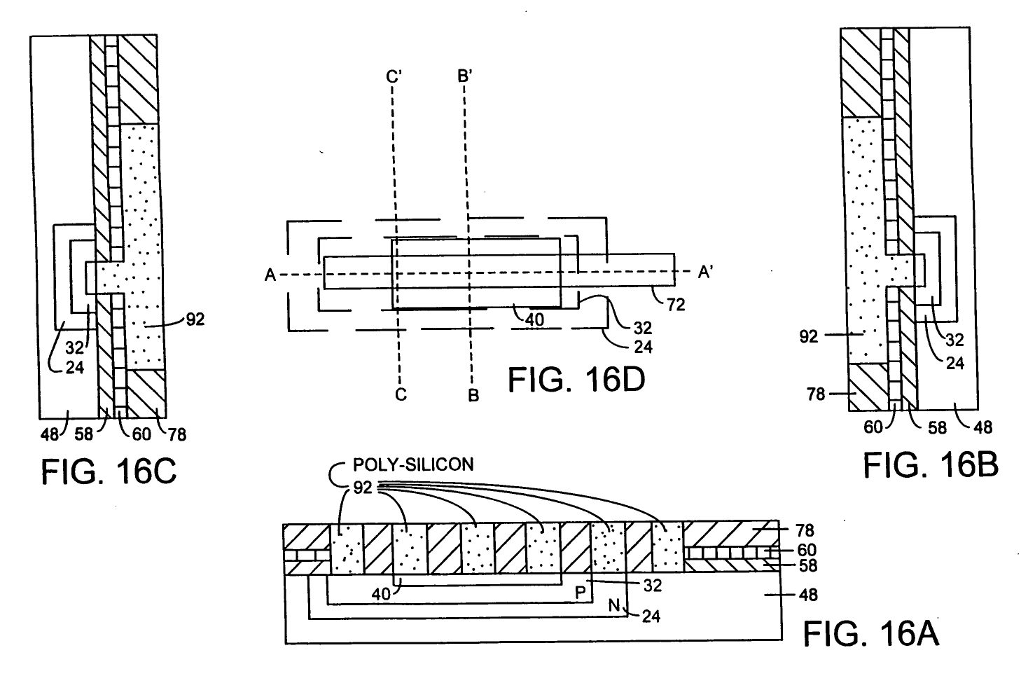

FIGS. 14A through 14D show the structure at a stage of construction after the N-well, P-well and N-type channel have been formed and the active area has been defined and a thick layer of silicon dioxide has been deposited and polished back so as to have a planar top surface. Because the silicon dioxide dips down into active area opening 72 formed in the underlying nitride layer 60 and thermal oxide layer 58, the top of the oxide layer 78 will have a dip in it at the location of every active area opening at every JFET device being formed on the chip. This will cause an uneven top surface of the oxide upon which later metallization layers will be formed to fabricate interconnects between various terminals in the circuit. In addition, photoresist does not like uneven surfaces so polishing the top of the oxide layer back to a flat surface using chemical mechanical polishing makes subsequent masking steps easier to perform. Because the next step in the process is to open multiple contact holes which may be as small at 65 nanometers wide, it is important to have a flat surface upon which to deposit photoresist to make an etch mask to form these small contact holes. This Chemical-Mechanical-Polishing (CMP) step eliminates the step coverage issue without any adverse affects on the JFET characteristics or performance. Insulating layer 78 can also be formed using any other insulating material compatible with the JFET integration process described herein. For example, a thin nitride layer 79 (represented by dashed lines because it is optional) can be added on top of the silicon dioxide layer 78 to act as a hard polish/etch stop to stop the removal of poly-silicon when contact holes are later formed in the insulating layer 78/79 and they are filled with poly-silicon and etched to form interconnect “wires” and polished back to the top of the insulating layer 78/79 to form a planar surface as shown in FIG. 16A.

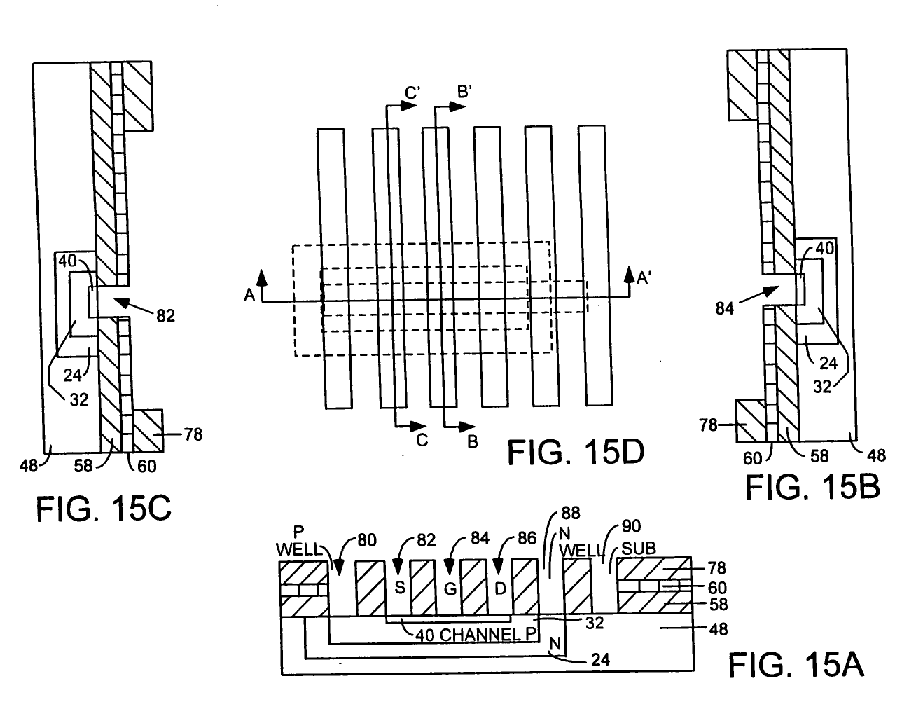

FIGS. 15A through 15D show the structure at a stage of construction after the N-well, P-well, N-type channel have been formed and the active area has been defined and a thick layer of silicon dioxide has been deposited and polished back and a plurality of contact holes have been masked and etched. This stage is reached by depositing photoresist and developing it to expose the top of the oxide layer at the location of contact holes 80, 82, 84, 86, 88 and 90. This same mask is used to define any interconnect channels that are to extend between active areas so that the conductive material of the source, gate, drain or well contacts may be extended across an expanse of substrate between active areas to make interconnects. Such an interconnect is shown in FIG. 5 as the wire 5 which connects the gate of P-channel device 1 to the gate of the N-channel device 3. These interconnect channels are basically channels etched in the silicon dioxide layer 78 down to the nitride layer 60 and extend from a terminal of one transistor to the terminal of another transistor or to some other node such as a power supply, ground pin, etc.

To form the contact openings and interconnect channels, a plasma etch is used. Note that over the active area, the nitride layer 60 has already been etched away in a previous etching step. However, over the substrate expanse outside the active area, the nitride layer 60 still exists. This nitride layer 60 acts as an etch stop to stop the plasma etch so as to define the bottom of the interconnect channel so that a single plasma etch may be used to form both the contact openings and the interconnect channels. This plasma etch etches away the CVD silicon dioxide layer 78 at the location of the contact holes 80, 82, 84, 86 88 and 90. At the locations of the interconnect channels, the plasma etch etches the CVD oxide layer 78 all the way down to the nitride layer 60. This also forms the connections between the interconnect channels and the contact openings.

FIGS. 19A and 19B illustrate one species of an interconnect structure according to one aspect of the teachings of the invention. FIG. 19A shows a plan view of an interconnect channel 100 that extends across an expanse of substrate between the active area 102 of a first transistor and the active area 104 of a second transistor. FIG. 19B shows a cross section through the interconnect structure within channel 100 taken along section line B-B′ in FIG. 19A. The interconnect channel 100 contains conductive material which electrically connects the gate terminal 106 of the first transistor to the gate terminal 108 of the second transistor. In the particular example illustrated, the conductive material is P+ doped poly-silicon 110 over the first transistor active area 102 and is N+ doped polysilicon 112 over the second transistor active area 104. A layer of silicide 114 covers the top surface of the poly-silicon so as to short out the PN junction 116 between the N+ and P+ poly-silicon. Note that the conductive material 110 and 112 is insulated at all points outside the active areas from the substrate by the silicon nitride layer 60 and the thermal oxide layer 58. Thus, the PN junctions at 118, 120, 122, 124, 126 and 128 are not shorted out, and the interconnect comprised of poly-silicon sections 111 and 112 are not connected electrically to any voltage source to which the substrate or any of the wells surrounding the active areas may be coupled to. Note also the flush top surface of the interconnect 111/112. This results from the interconnect channel being filled with a conductive material and then polished back to the top of insulating layer 56. The top of this insulating layer 56 may have an optional silicon nitride cap (shown in FIG. 14A) to act as an etch stop. The interconnect channel is a groove having the dimensions of interconnect path 100 in FIG. 19A and etched down to the silicon nitride layer 60 at all areas outside the active areas 102 and 104.

The interconnect conductor comprised of doped poly-silicon sections 111 and 112 with the silicide cap 114 may also be constructed of any metal. Specifically, the interconnect may be made of metals such as aluminum, copper, titanium, tungsten, gold, silver or any other conductive material that can withstand the electrical and environmental factors. If aluminum is used, a spiking barrier needs to be formed at the bottoms of gate contacts 132 and 134. To form aluminum interconnects, the contact openings and interconnect channels will be formed in the same way as previously described. Then a layer of titanium silicide will be formed at the bottom of each hole in a known manner to act as an ohmic contact. This is done by depositing titanium in the holes so as to be contact with the silicon of the substrate. The structure is then baked at about 700 degrees C. for about 30 minutes to form the silicide. A layer of titanium nitride or titanium/tungsten is then deposited to act as a spiking barrier to prevent aluminum atoms from diffusing down into the substrate. The contact opening and interconnect trench is filled up with aluminum and polished back to the top of layer 56. Likewise, copper can be used as the interconnect metal and contact structure for the transistors. This is done by forming a layer of titanium silicide in the bottom of each contact hole and then forming a tantalum sleeve on top of the silicide and covering the vertical walls of each contact opening. Then copper is deposited to fill the contact opening and the interconnect trenches and polished back to be flush with the top of insulator layer 56. Where metals are used for the contacts, a separate implant to form the gate region will have to be conducted.

Note that in some embodiments, the substrate could be insulating material with a layer of single crystal semiconductor epitaxially grown on top thereof. The term semiconductor layer in the claims is intended to cover both substrate which is all semiconductor or an semiconductor-on-insulator construction. Each contact hole will be filled with doped poly-silicon or metal (with a spiking barrier if necessary) to make contact with a structure below it as will be described later herein.

In alternative embodiments, some other etch stop material can be substituted for the nitride layer 60. Examples would be aluminum oxide, intrinsic poly-silicon or any other material which will stop the plasma etch short of reaching the substrate after it has etched through CVD oxide layer 78.

Note that the interconnect structure defined herein is applicable to any integrated transistor which does not use STI or field oxide to isolate active areas of transistors on the chip. That interconnect structure is: 1) no STI or field oxide insulating neighboring active areas; 2) an insulating layer on top of the substrate which exposes the active areas but which covers the expanse of substrate between the active areas and which has an etch stop as the top layer thereon; 3) contact holes etched down to the semiconductor of the active area and interconnect channels joining the contact holes but etched only down to the etch stop in the expanses between active areas so as to not expose the top of the semiconductor layer; 4) a conductive material such as doped poly-silicon with a silicide top or bottom layer or metal (including a spiking barrier is necessary at the bottom of the contact openings) filling the contact opening and interconnect channels, said conductive material having been polished back to the top of the insulating layer so as to be planar at the top surface over the contact openings and the interconnect channels, i.e., the top of the contact opening conductive material is flush with the top of the interconnect channel conductive material.

FIGS. 16A through 16D show the structure at a stage of construction after the N-well, P-well, N-type channel have been formed and the active area has been defined and thick layer of silicon dioxide has been deposited and polished back and a plurality of contact holes have been masked and etched, and the contact holes have been filled with poly-silicon and polished back. To reach this stage of construction, the etch mask is removed to expose the top of the oxide layer, and a layer 92 of poly-silicon is deposited by CVD. This layer is thick enough to fill the contact holes and cover the top of oxide layer 78. This poly-silicon layer 78 is then polished back to the top of the oxide layer 78 using Chemical Mechanical Polishing so as to leave a flat surface upon which the next set of doping masks can be formed.

In an important embodiment, the top layer of CVD oxide 78 is etched down to the nitride layer 60 using a interconnect mask. (See FIG. 8A and the Process Flow Table, below.) This etch forms interconnect channel to make possible poly-silicon or metal conductive interconnect lines which can extend the source contact 16, the drain contact 18, the gate contact 12, the N-well contact 26, the P-well contact 34 and the substrate contact 52 to other nodes in the circuit. The interconnect channels would be filled with poly-silicon in step 10 of the process flow table when the source, drain, etc. contact openings are filled with poly-silicon. In alternative embodiments, they can be filled with metal. Then, in step 10 when the CMP polish process is finished, the contacts and interconnects will have flat top surfaces which are flush with the insulating material surrounding the interconnect trenches. If poly-silicon is used, in steps 11 and 12 when the P+ and N+ implant masks are formed, the masks are formed so that the tops of the poly-silicon in the interconnect channels are exposed. If the interconnect channels extend from a P+ type contact, then the P+ implant mask is formed so as to expose the poly-silicon in that interconnect channel and all other interconnect channels are covered (all poly-silicon in interconnect channels from P+ type contacts are doped simultaneously with one P-type implant). If the interconnect channel extends from an N+ type contact, then the N+ implant mask is formed so as to expose the poly-silicon in that interconnect channel and all other interconnect channels are covered (all poly-silicon in interconnect channels from N+ type contacts are doped simultaneously with one N-type implant). Finally, silicide is formed on top of the poly-silicon in the interconnect channels in the same way and at the same time silicide is formed on the top surfaces of the contact structures 34, 16, 12, 18, 26 and 52 in FIG. 8A.

In other embodiments, the insulating layer formed on top of the substrate may be a different combination of materials or all one material and the interconnect trench may be etched separately from the contact openings. The interconnect trench etch must be such that the interconnect trench does not go all the way down through the insulation layer to the surface of the semiconductor layer of the substrate.

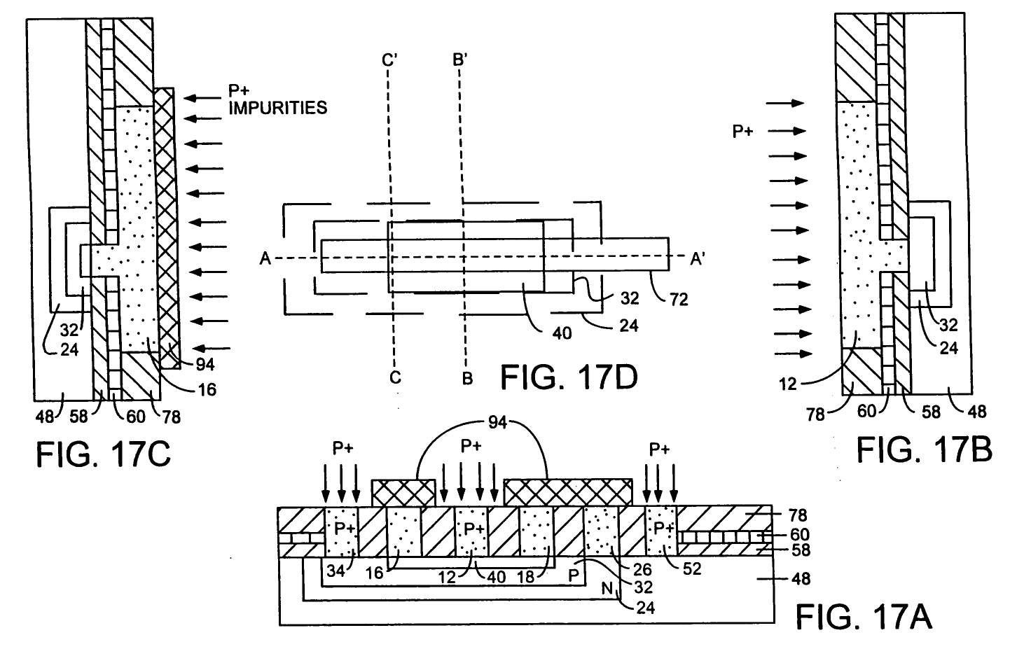

FIGS. 17A through 17D show the structure at a stage of construction after the N-well, P-well, and N-type channel have been formed and the active area has been defined and a thick layer of silicon dioxide has been deposited and polished back and a plurality of contact holes have been masked and etched, and the contact holes have been filled with poly-silicon and polished back, and a P+ impurity implant mask has been formed. To reach this stage of construction, the previous etch mask is removed and a new mask 94 is formed to cover the source and drain contact poly-silicon, 16 and 18 and the N-well contact poly-silicon 26 to prevent these regions of poly-silicon from being implanted. P-type impurities are then ion implanted into poly-silicon contacts 34, 12 and 52 to turn these poly-silicon regions into P+contacts to the underlying JFET structures. Multiple implants are preferred for better distribution of the implanted, conductivity-enhancing impurities. This P+ impurity implant is typically BF2 2E15 at 15 KEV and 2E15 at 36 KEV. This P+ implant creates P+ poly-silicon contacts 34, 12 and 52 to the P-well 32, gate region (not formed yet) and the P− substrate 48.

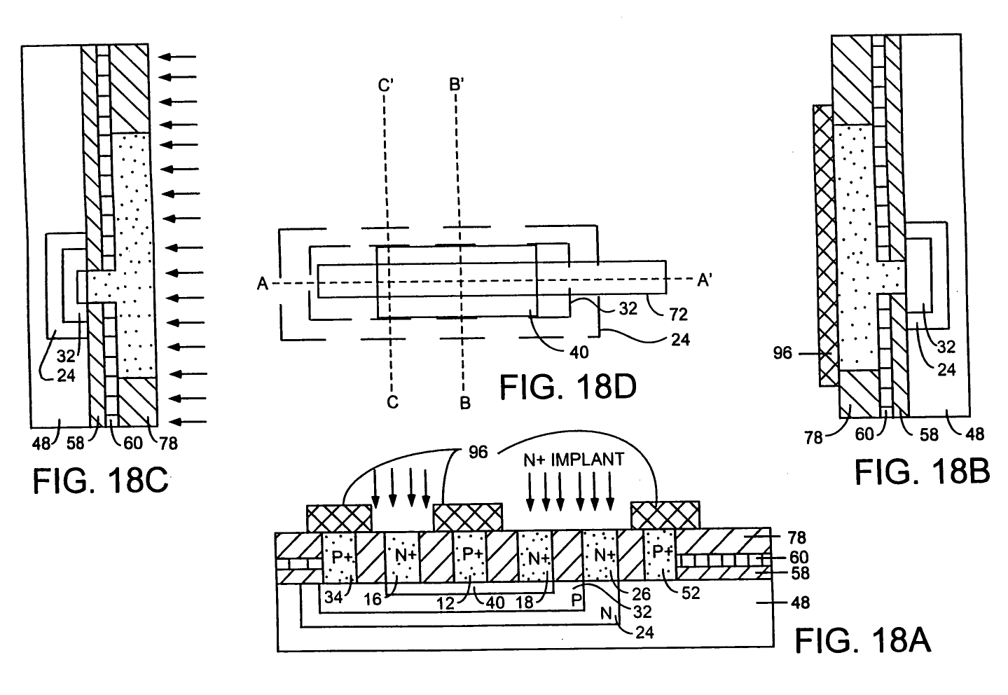

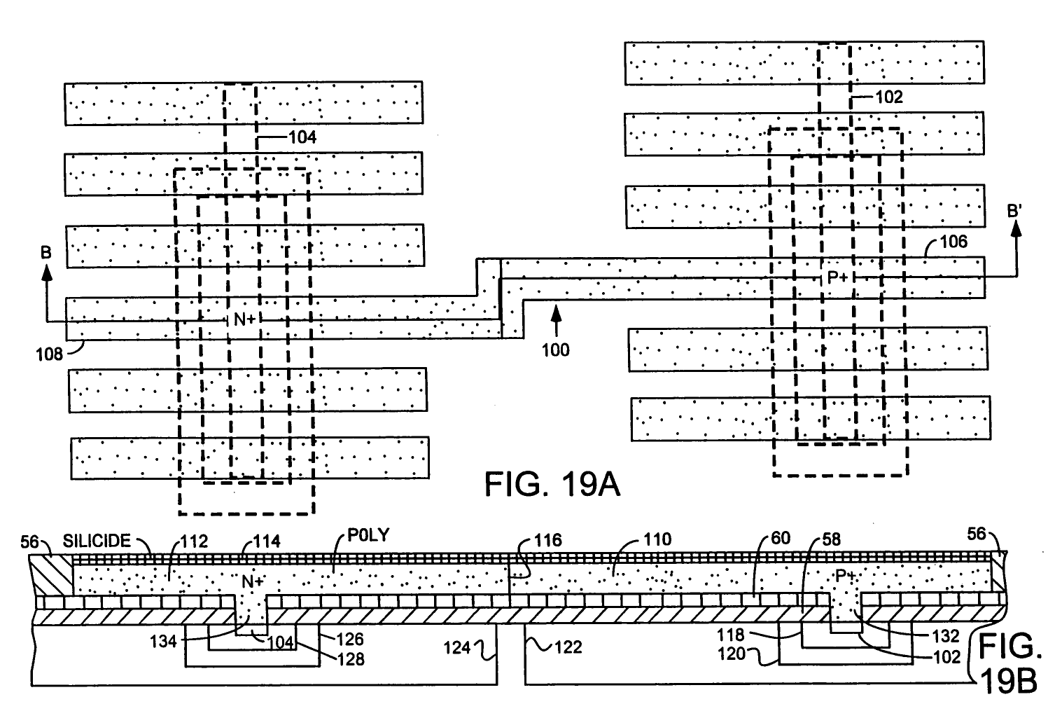

FIGS. 18A through 18D show the structure at a stage of construction after the N-well, P-well, N-type channel have been formed and the active area has been defined and thick layer of silicon dioxide has been deposited and polished back and a plurality of contact holes have been masked and etched, and the contact holes have been filled with poly-silicon and polished back, and a P+ impurity implant has been completed and an N+ implant mask has been formed. To reach this stage of construction from the state shown in FIGS. 17A through 17D, the P+ implant mask 94 is removed, and an N+ implant mask 96 is formed to cover the P+ doped, poly-silicon contact regions 52, 12 and 34. An N+ impurity implant is then performed (preferably several implants at different energies for better impurity distribution) to dope the poly-silicon contact areas 16, 18 and 26 to an N+ conductivity state). This N+ implant is typically arsenic at 1 E15 at 25 KEV.

The final steps leave the structure as shown in FIG. 8A which is the finished device. The first of these final steps is to strip the resist of mask 96 and do a thermal drive-in to drive the N+ and P+impurities into the underlying semiconductor substrate to form the P+ gate region 42 and N+ source and drain ohmic contacts 44 and 46 to the N-type channel 40. This thermal drive-in also forms ohmic contacts 38, 30 and 50 to the P-well 32, the N-well 24 and the P− substrate 48, respectively. Note that the thermal drive-in method of forming the gate region 42 and the source and drain regions 44 and 46 and the ohmic contacts 38, 30 and 50 makes the gate region and the source and drain regions self-aligned. The thermal drive-in step also serves to anneal the implants and is typically done at 900 degrees C. for approximately one to five seconds.

Next, a layer of silicide is formed on top of each poly-silicon contact to reduce its resistance and short out any PN junctions which get inadvertently formed when the poly-silicon contacts are extended to make contact with other nodes in the integrated circuit. The silicide layers are shown at 36, 20, 14, 22, 28 and 54 in FIG. 8A. These layers are formed by depositing titanium over the entire surface of the chip and then baking the structure at a temperature high enough, typically 700 degrees Centigrade, and for a period long enough, typically 30 minutes, that the titanium reacts with the poly-silicon contacts to form a layer of silicide on the top of each contact. The remaining titanium on top of the CVD oxide layer 56 is then dipped off (etched off in a suitable solution to dissolve titanium but not the other structures) to complete the structure.

By using the surface contacts to apply bias voltages to reverse-bias the PN junction between the N-well 24 and the P− substrate 48, it is possible to isolate each device from other devices on the circuit without the use of field oxide. By keeping the operating voltage below 0.7 volts, no latching occurs.

PROCESS FLOW TABLE

| Step | | |
|---|---|---|
| Number | Figure Number | Processing Step |
| 1 | FIGS. 9A–9D | Start with <100> silicon substrate 48 doped P− or use |
| | | germanium, silicon-carbide and silicon-germanium- |
| | | carbon alloy semiconductor substrate |
| 2 | FIGS. 9A–9D | Thermally grow about 100 A of silicon dioxide, and then |
| | | deposit about 200 A of silicon nitride |
| 3 | FIGS. 9A–9D | Form mask 62 to expose area for N-well 24 and implant |
| | | N-well through nitride and oxide layers. Implant energy |
| | | is approximately 50 KEV with a dose of 5E11. An N- |
| | | well drive-in at 950 degrees C is then performed. |
| | | Multiple implants at different energies are preferred for |
| | | best distribution of conductivity enhancing impurities. |
| 4 | FIGS. 10A–10D | Remove previous step mask, and form new mask 64 to |
| | | expose area for P-well 32 and implant P-well through |
| | | nitride and oxide layers. Implant energy is less than |
| | | approximately 50 KEV with a dose of 5E11 so that P- |
| | | well is encompassed by N-well. An P-well drive-in at |
| | | 950 degrees C is then performed. Multiple implants at |
| | | different energies are preferred for best distribution of |
| | | conductivity enhancing impurities. |
| 5 | FIGS. 11A–11D | Remove previous step mask, and form new mask 70 to |
| | | expose surface of substrate to define the location and size |
| | | of the active area. Etch silicon nitride layer 60 and silicon |
| | | dioxide layer 58 down to surface of substrate. Preferably |
| | | a plasma etch is used which is set up to detect the |
| | | presence of silicon atoms in the gases produced by the |
| | | etching process so as to stop etching when the surface of |
| | | the substrate is reached. |
| 6 | FIGS. 12A–12D | Remove the mask 70 and form a new mask 76 to expose |
| | | the area where the channel implant is to be made. Do |
| | | multiple N-type impurity channel implants at 15 KEV, |
| | | dose 1E13 followed by 37 KEV, dose 4E11 preferably to |
| | | establish channel-P-well junction depth at approximately |
| | | 40–50 nanometers and achieve good impurity |
| | | distribution. |
| 7 | FIGS. 13A–13D | Remove mask 76 and deposit a thick layer 78 of silicon |
| | | dioxide - typically about 7000 A |
| 8 | FIGS. 14A–14D | Polish back top layer of silicon dioxide layer 78 to form a |
| | | flat top surface. |
| 9 | FIGS. 15A–15D | Deposit photoresist and develop to form mask to expose |
| | | areas where source, drain, gate, P-well, N-well and |
| | | substrate contacts are to be formed and to define the |
| | | interconnect channels where conductive material forming |
| | | a contact to a terminal of one transistor will be extended |
| | | across the substrate expanse between active areas to |
| | | make contact to a terminal of another transistor. Plasma |
| | | etch down to substrate top surface over the active area to |
| | | form contact holes. Etch down to nitride layer 60 in |
| | | areas where interconnect channels are to be formed. In |
| | | alternative embodiments where some different |
| | | combination of insulating materials or a single layer of |
| | | insulating material is used, etch the interconnect channels |
| | | only part way down through the insulation layer so as to |
| | | not expose the top surface of the substrate. |
| 10 | FIGS. 16A–16D | Fill contact holes with CVD polysilicon and polish back |
| | | to top of oxide layer 78 using Chemical Mechanical |
| | | Polishing (CMP). |
| 11 | FIGS. 17A–17D | Deposit photoresist and develop to form P+ implant mask |
| | | 94 to cover poly-silicon areas 16, 18 and 26. Implant P+ |
| | | impurities into poly-silicon areas 34, 12 and 52.). This |
| | | P+ implant is typically BF2 2E15 at 15 KEV and 2E15 at |
| | | 36 KEV. |
| 12 | FIGS. 18A–18D | Remove P+ implant mask 94, deposit photoresist and |
| | | develop to form N+ implant mask 96 covering poly- |
| | | silicon areas 34, 12 and 52. Perform N+ implant to |
| | | convert poly-silicon areas 16, 18 and 26 to N+ |
| | | conductivity.). This N+ implant is typically arsenic at |
| | | 1E15 at 25 KEV. |
| 13 | FIGS. 8A–8D | Remove implant mask 96 and thermally drive in |
| | | impurities from N+ and P+ doped poly-silicon contacts to |
| | | form a self-aligned gate region 42, self-aligned source |
| | | and drain regions 44 and 46, respectively, and ohmic |
| | | contacts for the P-well, N-well and substrate. |
| 14 | FIGS. 8A–8D | Deposit titanium over entire surface and bake structure at |
| | | a temperature and for a time sufficient to form suicide on |
| | | top of each poly-silicon contact. Dip off excess titanium. |
| 15 | Not shown | Deposit insulating layer over entire structure and form |
| | | contact holes and form metal interconnect layers as |
| | | needed to complete whatever circuit is being built |

What is claimed is:

1. A Junction Field Effect Transistor structure comprising:
a semiconductor substrate doped to a first conductivity type;
a first well formed in said substrate and doped to a second conductivity type;
a second well formed in said first well and doped to a first conductivity type;
a channel region formed in said second well and doped to said second conductivity type;
a self-aligned gate region formed in said channel region and doped to said first conductivity type;
self-aligned source and drain regions formed in said channel region and doped to said second conductivity type;
doped polysilicon contact means for making individual electrical contacts to said substrate, said first and second wells, said self-aligned source and drain regions and said self-aligned gate region.

2. The device of claim 1 wherein semiconductor substrate comprises a material selected from a group comprising silicon, germanium, silicon carbide, and silicon-germanium-carbon alloy.

3. The device of claim 1 wherein said channel regions and gate region are formed in epitaxially deposited silicon semiconductor formed on an insulating substrate.

4. The device of claim 1 wherein said gate region comprises one or more layers of silicon-germanium-carbon alloy.

5. The device of claim 1 wherein said contact means each comprises poly-silicon doped with a conductivity enhancing impurity of the same conductivity type as the structure with which said contact means makes electrical contact and a layer of titanium silicide on a top surface of said contact means.

6. The device of claim 1 wherein the top surface of said doped poly-silicon contact means is flush with surrounding insulating material so as to form a flat surface.

7. An integrated Junction Field Effect Transistor comprising:
a substrate having at least a top layer of semiconductor doped to a first conductivity type with no shallow trench isolation or other field oxide or other insulating material formed in said semiconductor;
a multiple-well structure formed in said substrate comprising a first well doped to a second conductivity type so as to form a first PN junction with said substrate and a second well within said first well and doped to a first conductivity type so as to form a PN junction with said first well;
a channel region having source and drain regions formed therein;
a gate region formed in said channel region; and
an electrically conductive contact structure forming electrically isolated and separate electrical contacts to each of said substrate, said first well, said second well, said source region, said drain region and said gate region.

8. The device of claim 7 wherein said source and drain regions and said gate region are each self-aligned with the contact structure above said region.

9. The device of claim 7 wherein said contact structures are metal or doped poly-silicon which has been polished back to be flush with the top surface of an insulating layer formed on top of said substrate and which has had contact holes formed therein which are filled with said metal or doped poly-silicon, and, if meal is used for one or more of said contacts, each contact opening will have a ohmic contact formed in the bottom of the contact and a spiking barrier will be formed if necessary on top of said ohmic contact to prevent diffusion of metal atoms into said semiconductor of said substrate.

10. A process for making a junction-isolated Junction Field Effect Transistor, comprising the steps:
A) thermally growing a silicon dioxide layer on top of a substrate having at least a semiconductor layer which is doped P−;
B) depositing a layer of silicon nitride on said silicon dioxide layer formed in step A;
C) masking to expose an area where an N-well is to be formed and implanting N-type impurities into said semiconductor layer to form an N-well;
D) removing the mask formed in step C and forming a new mask to expose an area where a P-well is to be formed and implanting P-type impurities to form a P-well inside said N-well;
E) removing the mask formed in step D and forming a new mask to define an active area and etching through said silicon nitride and silicon dioxide layers to expose the top surface of said semiconductor layer;
F) removing the mask formed in step E and forming a new mask to expose an area within said active area where a channel implant is to be made and implanting N-type impurities into said active area to form an N-type channel region;
G) removing the mask formed in step F and depositing a layer of silicon dioxide which is thick enough to cover the entire surface of the structure and fill up the etched hole in the insulation layers formed in steps A and B where the active area is;
H) polishing back the layer of silicon dioxide formed in step G until the top surface thereof is generally flat;
I) forming a mask to expose areas where source, drain, gate, P-well, N-well and substrate contacts are to be formed and etching contact opening down to the surface of said active area using said mask to define the size and location of each contact opening;
J) depositing a layer of poly-silicon on the surface of said structure to fill said contact openings;
K) polishing said poly-silicon layer back to the top of said silicon dioxide layer formed in step H so as to form a generally flat surface;
L) forming a P+ implant mask to cover all but the poly-silicon areas which are to be doped P+ and implanting P-type impurities into said exposed poly-silicon areas;
M) removing the mask formed in step L and forming a new N+ implant mask to cover all but the poly-silicon areas which are to be doped N+ and implanting N-type impurities into said exposed poly-silicon areas;
N) removing the mask formed in step M and thermally driving in the impurities implanted in said poly-silicon areas to form a source, drain and gate region and ohmic contacts to said N-well, P-well and substrate; and
O) forming a layer of titanium silicide on top of said poly-silicon contact structures, and dipping off the excess titanium.

11. The process of claim 10 wherein said implant energy of the highest energy implant is approximately 50 KEV and the dosage is 5E11 and multiple implants are performed at different energy levels to achieve better impurity distribution and wherein said implant step includes an annealing and thermal drive in step where the structure is heated to approximately 950 degrees C. for a time sufficient to anneal the structure so as to activate the implanted impurities.

12. The process of claim 10 wherein said implant step of step D is carried out at a peak energy level which is such as to form said P-well within the boundaries of said N-well and wherein said implant step includes a high temperature annealing and thermal drive in step to activate the implanted impurities.

13. The process of claim 10 wherein said channel implant is carried out using multiple implants, one at approximately 15 KEV with a dose of approximately 1 E13 followed by one at approximately 37 KEV with a dose of approximately 4E11.

14. The process of claim 10 wherein the implant step of step L is carried out at approximately 15 KEV with BF2 impurities at a dosage of 2E15 and another implant at 36 KEV and 2E15 dosage.

15. The process of claim 10 wherein the implant step of step M is carried out at approximately 25 KEV with arsenic impurities at a dosage of approximately 1 E15.

16. A process for making a junction-isolated Junction Field Effect Transistor, comprising the steps:
A) thermally growing a silicon dioxide layer on top of a substrate having at least a semiconductor layer which is doped P−;
B) depositing a layer of etch stop insulating material such as silicon nitride, undoped poly-silicon, aluminum oxide or any other material which can stop a plasma etch on said silicon dioxide layer formed in step A;
C) masking to expose an area where an N-well is to be formed and implanting N-type impurities into said semiconductor layer to form an N-well;
D) removing the mask formed in step C and forming a new mask to expose an area where a P-well is to be formed and implanting P-type impurities to form a P-well inside said N-well;
E) removing the mask formed in step D and forming a new mask to define an active area and etching through said etch stop insulating material and silicon dioxide layers to expose the top surface of said semiconductor layer;
F) removing the mask formed in step E and forming a new mask to expose an area within said active area where a channel implant is to be made and implanting N-type impurities into said active area to form an N-type channel region;
G) removing the mask formed in step F and depositing one or more layers of insulating material such as a layer chemical vapor deposition silicon dioxide or a layer of chemical vapor deposition silicon dioxide topped by a layer of etch stop insulating material, said one or more layers of insulating material being thick enough to cover the entire surface of the structure and fill up the etched hole in the insulation layers formed in steps A and B where the active area is;
H) polishing back said one or more layers of insulating material formed in step G until the top surface thereof is generally flat;
I) forming a contact/interconnect mask to expose areas where source, drain, gate, P-well, N-well and substrate contacts and interconnect channels between active areas of different devices are to be formed and etching contact opening down to the surface of said active area using said mask to define the size and location of each contact opening, said etching step also forming said interconnect channels by etching down to said etch stop insulating material in the areas exposed by said contact/interconnect mask, and, if metal is to be used for a gate contact, masking and performing an implant through said gate contact opening to form a self-aligned gate region of the proper conductivity type for the JFET device being formed;
J) if metal contacts are to be formed using a metal which has a spiking problem where metal atoms diffuse into the semiconductor of said substrate, forming an ohmic contact in the bottom of each contact opening where such metal is to be used and forming a spiking barrier on top of each said ohmic contact;
K) depositing a layer of conductive material such as metal or poly-silicon on the surface of said structure to fill said contact openings and said interconnect channels;
L) polishing said layer of conductive material formed in step K down to the top of said one or more layers of insulating material formed in step H so as to form a generally flat surface;
M) if poly-silicon was used to fill said contact openings, forming a P+ implant mask to cover all but the poly-silicon areas which are to be doped P+ and implanting P-type impurities into said exposed poly-silicon areas;
N) if poly-silicon was used to fill said contact openings, removing the mask formed in step M and forming a new N+ implant mask to cover all but the poly-silicon areas which are to be doped N+ and implanting N-type impurities into said exposed poly-silicon areas;
O) if poly-silicon was used to fill said contact openings, removing the mask formed in step N and thermally driving in the impurities implanted in said poly-silicon areas to form a source, drain and gate region and ohmic contacts to said N-well, P-well and substrate; and
P) if poly-silicon was used to form said contacts and fill said interconnect channel(s), forming a layer of silicide on top of said poly-silicon to enhance the conductivity thereof, and dipping off the excess metal used to form said silicide.

17. The process of claim 16 wherein said semiconductor is silicon and wherein step J comprises depositing a layer of titanium in the bottom of each contact hole and baking it for a time sufficient to form titanium silicide as an ohmic contact and then depositing a titanium/tungsten spiking barrier layer, and wherein step K comprising depositing a layer of aluminum above said spiking barrier in each contact hole and so as to fill said interconnect channels.

18. A method for forming an interconnect conductor between nodes such as contacts over active areas of transistors in an integrated circuit having no Shallow Trench Isolation or field oxide between active areas of transistors comprising the steps:
A) depositing a layer of insulating material on the surface of a semiconductor layer of a substrate;
B) depositing an etch stop insulating material on top of said layer of insulating material deposited in step A;
C) masking to define a plurality of active areas for transistors, D) etching down through said etch stop insulating material and said layer to insulating material to expose a surface of said semiconductor layer so as to form one or more active area for one or more transistors;
E) depositing a layer of insulating material over said structure so as to cover said active area and regions surrounding said active area and polishing said insulating material back to a flat surface;
F) masking to expose a plurality of contact openings over said one or more active areas and to expose one or more interconnect channels between contact openings of active areas or between a contact opening and another node on said integrated circuit;
G) etching down to the semiconductor surface over the active areas and down to the etch stop insulating layer outside the active area to form said contact openings and said interconnect channels;
H) filling said contact openings and said interconnect channels with conductive material and polishing said conductive material back so as to as to be flush with the top surface of said insulating layer formed in step E.

19. The process of claim 18 wherein step H comprises filling said contact openings with poly-silicon and then doping said poly-silicon with the proper conductivity enhancing impurities in the various contact openings and the interconnect channels, with the type of impurities used to dope each contact being dependent upon the type of device being formed, and then forming a layer of silicide on top of said doped poly-silicon to improve its conductivity.

20. The process of claim 18 wherein step H comprises filling said contact openings with titanium or some other metal suitable for forming a silicide ohmic contact and then forming said silicide, and then deposing one or more metals such as titanium/tungsten or other metal or metals capable of preventing diffusion of aluminum atoms into said semiconductor of said substrate, and then depositing aluminum in said contact holes and said interconnect channels and polishing the aluminum back to be flush with the top surface of the insulating layer formed in step E.

21. The process of claim 18 wherein step H comprises filling said contact openings with titanium or some other metal suitable for forming a silicide ohmic contact and then forming said silicide, and then forming a layer of one or more metals such as tantalum or other metal or metals capable of preventing diffusion of copper atoms into said semiconductor of said substrate on top of said ohmic contact and so as to line the walls of said contact openings, and then depositing copper in said contact holes and said interconnect channels and polishing the copper back to be flush with the top surface of the insulating layer formed in step E.

22. A method for forming an interconnect conductor between nodes in an integrated circuit having no Shallow Trench Isolation or field oxide between active areas of transistors comprising the steps:
A) depositing a layer of insulating material on the surface of a semiconductor layer of a substrate wherein said insulating layer is comprised of a first layer of silicon dioxide, an intermediate layer of silicon nitride, and a top layer of chemical vapor deposition silicon dioxide;
B) etching an active area opening in said layer of insulating material formed in step A all the way down to a top surface of said semiconductor layer;
C) depositing a layer of insulating material so as to fill the opening over said active area;
D) masking and etching in the insulating layer formed in step C a contact hole and an interconnect channel joining said contact opening, said contact opening being etched down to the substrate, and said interconnect channel being etched down through said insulating layer formed in step C to the top of said silicon nitride layer formed in step A;
E) filing said contact opening and interconnect channel with conductive material and polishing the conductive material back so as to be flush with a top surface of the layer of insulating material formed in step C at locations outside the interconnect channel and contact opening.

23. An interconnect structure for an integrated circuit having a substrate in which one or more active areas are defined, comprising:
a semiconductor substrate having one or more active areas where transistor or other devices are to be formed;
a layer of first insulating material on top of said substrate surrounding said one or more active areas;
a layer of etch stop insulating material formed atop said first insulating material;
a layer of second insulating material formed so as to cover said active area and lie atop said layer of etch stop insulating material;
a contact opening etched down through said second insulating material to said semiconductor substrate and an interconnect channel etched down to said layer of etch stop insulating material at locations outside said active area and joining said contact opening; and
conducting material which fills said contact opening and said interconnect channel and which has been polished or etched or otherwise processed so as to be flush with the top surface of said second insulating layer.

24. A semiconductor contact and interconnect structure on an integrated circuit, comprising:
a substrate having a single crystal semiconductor layer;
any transistor structure integrated into said semiconductor layer and needing contacts to terminals of the transistor, each transistor structure formed in an active area in said semiconductor layer which is isolated from other transistors on said integrated circuit by any means other than Shallow Trench Isolation or field oxide;
an insulating layer formed on a top surface of said semiconductor layer and having an etch stop layer on top thereof and a second insulating layer formed atop said etch stop layer;
a contact opening etched in said insulating layer down to said top surface of said semiconductor layer at said active area;
an interconnect channel etched down through said second insulating layer to said etch stop layer;
a layer of conductive material filling said contact opening and said interconnect channel and polished back so as to be flush with a top surface of said second insulating layer.

25. The device of claim 24 wherein said layer of conductive material is a layer of doped poly-silicon, said doped poly-silicon having been polished back so as to have a top surface which is approximately flush with a top surface of said second insulating layer, said doped poly-silicon having a layer of silicide formed atop thereof to enhance the conductivity of said poly-silicon.

26. The structure of claim 25 wherein said layer of conductive material is tungsten.

27. The structure of claim 25 wherein said layer of conductive material is aluminum with a metal silicide ohmic contact at the bottom of said contact opening and a spiking barrier metal or alloy on top of said ohmic contact and between said aluminum and said semiconductor substrate.

28. A method for forming an interconnect conductor between nodes in an integrated circuit having no Shallow Trench Isolation or field oxide between active areas of transistors comprising the steps:
A) depositing a layer of insulating material on the surface of a semiconductor layer of a substrate;
B) etching an active area opening in said layer of insulating material formed in step A all the way down to a top surface of said semiconductor layer;
C) depositing a layer of insulating material so as to fill the opening over said active area;
D) masking and etching in the insulating layer formed in step C a contact hole said contact opening being etched down to the substrate;
E) masking and etching in said insulating layer formed in step C an interconnect channel, said interconnect channel joining said contact opening and being etched part way down through said insulating layer formed in step C and possibly part way down through said insulating layer formed in step A but not so far as to reach said substrate;
F) filing said contact opening and interconnect channel with conductive material and polishing the conductive material back so as to be flush with a top surface of the layer of insulating material formed in step C at locations outside the interconnect channel and contact opening.
